(19) United States
(12) Patent Application Publication
(10) Pub. No.: US 2007/0145525 A1
(43) Pub. Date: Jun. 28, 2007

(54) MIM CAPACITOR STRUCTURE AND METHOD OF MANUFACTURING THE SAME

(75) Inventors: Ching-Chiun Wang, Miaoli County (TW); Cha-Hsin Lin, Tainan City (TW); Wen-Miao Lo, Kaohsiung City (TW); Lurng-Shehng Lee, Hsinchu County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: INDUSTRIAL TECHNOLOGY RESEARCH INSTITUTE, Hsinchu (TW)

(21) Appl. No.: 11/463,893

(22) Filed: Aug. 11, 2006

(30) Foreign Application Priority Data
Dec. 26, 2005 (TW) 94146470

(51) Int. Cl. H01L 29/00

(52) U.S. Cl. 257/532; 257/E21.021

(57) ABSTRACT

A metal-insulator-insulator (MIM) capacitor structure is provided. The MIM capacitor includes a top electrode, a bottom electrode and a dielectric layer. The dielectric layer is disposed between the top electrode and the bottom electrode. The main feature for this kind of MIM capacitor is that the bottom electrode includes a conductive layer and a metal nitride with multi-layered structure. The metal nitride with multi-layered structure is disposed between the conductive layer and the dielectric layer. The nitrogen content in the metal nitride with multi-layered structure gradually increases toward the dielectric layer and the metal nitride belongs to the amorphous type. Due to the presence of the metal nitride, the dielectric layer is prevented from crystallization, thereby reducing the current leakage of the MIM capacitor.

### CROSS-REFERENCE TO RELATED APPLICATION

This application claims the priority benefit of Taiwan application serial no. 94146470, filed Dec. 26, 2005. All disclosure of the Taiwan application is incorporated herein by reference.

### BACKGROUND OF THE INVENTION

1. Field of the Invention

The present invention relates to a metal-insulator-metal (MIM) capacitor and method of manufacturing the same. More particularly, the present invention relates to a metal-insulator-metal (MIM) capacitor structure and method of manufacturing the same that can avoid bottom electrode induced crystallization of the insulator.

2. Description of the Related Art

Metal-insulator-metal (MIM) capacitor has gradually become the capacitor for the next generation of dynamic random access memory (DRAM). Furthermore, using high dielectric constant (high-k) material to fabricate the insulation layer, sufficient capacitance can be obtained when the capacitor area is reduced. Because electrode material in a crystalline state has a lower resistance and a better conductive effect, the electrodes of most metal-insulator-metal (MIM) capacitor are of this type. However, during the process of fabricating the capacitor, a crystalline electrode material often induces its overlying insulating material to crystallize. Hence, a greater leakage current will be produced for the high dielectric constant material. The reason for this is that the presence of grain boundaries inside the crystalline material is a significant factor for the loss of electric charges. Furthermore, the thermal stability of the capacitor in a subsequent high-temperature treatment of the transistor fabrication will deteriorate, and ultimately, the capacitance of the capacitor will decrease.

### SUMMARY OF THE INVENTION

Accordingly, at least one objective of the present invention is to provide a metal-insulator-metal (MIM) capacitor structure having a smaller leakage current.

At least another objective of the present invention is to provide a method for fabricating a metal-insulator-metal (MIM) capacitor that can improve the quality of the capacitor and significantly increase the applicability of using high dielectric constant film material in DRAM capacitor devices.

To achieve these and other advantages and in accordance with the purpose of the invention, as embodied and broadly described herein, the invention provides a metal-insulator-metal (MIM) capacitor structure. The MIM capacitor includes a top electrode, a bottom electrode and a dielectric layer. The dielectric layer is disposed between the top electrode and the bottom electrode. The feature of this kind of MIM capacitor is that the bottom electrode comprises a conductive layer and a metal nitride with multi-layered structure. The metal nitride with multi-layered structure is disposed between the conductive layer and the dielectric layer. The nitrogen content in the metal nitride with multi-layered structure gradually increases toward the dielectric layer and the metal nitride with multi-layered structure is amorphous type.

The present invention also provides a method of fabricating a metal-insulator-metal (MIM) capacitor. First, a conductive layer is provided. Then, a metal nitride with multi-layered structure is formed over the conductive layer. The metal nitride with multi-layered structure and the conductive layer together form a bottom electrode. The metal nitride with multi-layered structure is amorphous and the nitrogen content increases with the number of layers in the bottom electrode. Thereafter, a dielectric layer is formed over the metal nitride of the bottom electrode and then a top electrode is formed on the dielectric layer.

In the present invention, the bottom electrode close to the dielectric layer is fabricated using an amorphous metal nitride with multi-layered structure and the nitrogen content within the metal nitride with multi-layered structure gradually increases toward the direction of the dielectric layer. Hence, the degree of crystallinity in the dielectric layer is substantially reduced and further the quality of the capacitor is significantly improved.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a schematic cross-sectional view of a metal-insulator-metal (MIM) capacitor structure according to one embodiment of the present invention.

FIG. 2 is a flow diagram showing the steps for forming a metal-insulator-metal (MIM) capacitor according to another embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

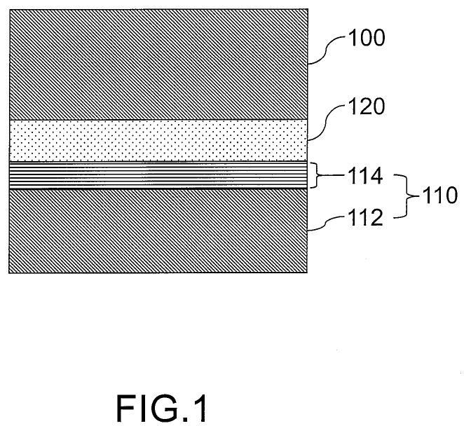

FIG. 1 is a schematic cross-sectional view of a metal-insulator-metal (MIM) capacitor structure according to one embodiment of the present invention. As shown in FIG. 1, the metal-insulator-metal (MIM) capacitor includes a top electrode 100, a bottom electrode 110 and a dielectric layer 120. The dielectric layer 120 is disposed between the top electrode 100 and the bottom electrode 110. Furthermore, the bottom electrode 110 comprises a conductive layer 112 and a metal nitride with multi-layered structure 114. The metal nitride with multi-layered structure 114 is disposed between the conductive layer 112 and the dielectric layer 120. The nitrogen content within the metal nitride with multi-layered structure 114 increases toward the direction of the dielectric layer 120. Moreover, the metal nitride with multi-layered structure 114 is amorphous type.

As shown in FIG. 1, the foregoing metal nitride with multi-layered structure 114 comprises a plurality of ultra-thin films. Each ultra-thin film has a thickness between several angstroms (Å) to several tens of angstroms (Å), but preferably between 5 Å to 10 Å, for example. Furthermore, the number of ultra-thin films in the metal nitride with multi-layered structure 114 is more than three, for example. The metal nitride with multi-layered structure 114 is fabricated using titanium nitride (TiN) or tantalum nitride (TaN), for example. The conductive layer 112 is fabricated using a suitable conductive material such as titanium nitride (TiN), tantalum nitride (TaN), ruthenium (Ru), platinum (Pt) or polysilicon (poly-Si). Therefore, a substantially same material or different materials can be used to fabricate the conductive layer 112 and the metal nitride with multi-layered structure 114. When a material of the metal nitride with multi-layered structure 114 is substantially the same as that of the conductive layer 112, the adhesion between them can be enhanced. Thus, the metal nitride with multi-layered structure 114 can be regarded as a buffer layer between the conductive layer 112 and the dielectric layer 120. In addition, this can effectively reduce the manufacture cost. On the other hand, a material of the dielectric layer 120 is preferably a high dielectric constant (high-k) material such as tantalum oxide (Ta₂O₅), aluminum oxide (Al₂O₃), hafnium aluminum oxide (HfₓAl_{y}O), hafnium oxide (HfO₂) or titanium oxide (TiO₂).

In the present embodiment, because an amorphous metal nitride with multi-layered structure is used, it is difficult to transform the dielectric layer into a crystalline state. Hence, the dielectric layer can exhibit an excellent thermal stability in subsequent high temperature process. In the meantime, the interface properties between the bottom electrode and the dielectric layer are improved, resulting in an effective enhancement on the performance quality of the metal-insulator-metal (MIM) capacitor.

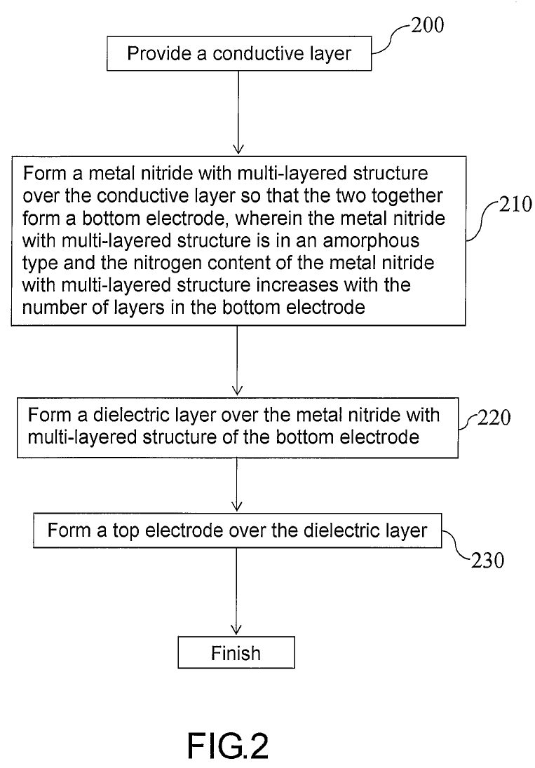

FIG. 2 is a flow diagram showing the steps for forming a metal-insulator-metal (MIM) capacitor according to another embodiment of the present invention. As shown in FIG. 2, in step 200, a conductive layer fabricated using a suitable conductive material such as titanium nitride (TiN), tantalum nitride (TaN), ruthenium (Ru), platinum (Pt) or polysilicon is provided.

In step 210, a metal nitride with multi-layered structure is formed over the conductive layer so that the metal nitride with multi-layered structure and the conductive layer together form a bottom electrode. The metal nitride with multi-layered structure is amorphous type. Furthermore, the nitrogen content in the metal nitride with multi-layered structure increases with the number of layers in the bottom electrode. This step can be carried out using a vacuum thin film deposition system such as a chemical vapor deposition (CVD) or atom layer deposition (ALD) system.

In addition, if a material of the conductive layer is substantially the same as that of the metal nitride with multi-layered structure, the processing operation can be simplified by changing a few processing parameters after coating the conductive layer to form the metal nitride with multi-layered structure in a continuous manner. For example, when a plasma-assisted atom layer deposition system is used, a precursor compound titanium tetrachloride (TiCl₄) is passed into a reaction chamber. Then, a purging process is carried out to remove the residual precursors. Thereafter, plasma containing a reactive gas of nitrogen and hydrogen (N₂/H₂) is passed into the reaction chamber. This process is performed in cycles to form a titanium nitride (TiN) film having a thickness, for example, of several angstroms serving as the conductive layer of the bottom electrode. Then, the precursor material used for the titanium nitride (TiN) is turned off, and the parameters for coating a titanium nitride (TiN) film are set to deposit ultra-thin TiN film on the surface. In the meantime, the nitrogen content in the deposition increases with the number of ultra-thin films laid, thereby forming the metal nitride with multi-layered structure of the bottom electrode. The foregoing ultra-thin film is very thin (the thickness is from several angstroms to several tens of angstroms). Because the crystallization degree of the metal nitride decreases with the ratio of nitrogen (N) to the metal (Ti or Ta) and the film thickness, the metal nitride with multi-layered structure will be formed with a mostly amorphous type. Furthermore, because a high-temperature treatment is often carried out in a subsequent process so that an inter-diffusion of the molecules between the conductive layer and the dielectric layer is likely to occur, the foregoing metal nitride with multi-layered structure also can serve as a diffusion barrier layer.

In step 220, a dielectric layer is formed over the metal nitride with multi-layered structure of the bottom electrode. A material of the dielectric layer is preferably a high dielectric constant (high k) material such as tantalum oxide (Ta₂O₅), aluminum oxide (Al₂O₃), hafnium aluminum oxide (HfₓAl_{y}O), hafnium oxide (HfO₂) or titanium oxide (TiO₂). Because the dielectric layer is formed on the aforementioned amorphous metal nitride with multi-layered structure instead of a crystalline electrode in a conventional structure, leakage current of the capacitor is reduced considerably so that a higher capacitance can be obtained.

Finally, in step 230, a top electrode is formed over the dielectric layer.

In summary, one particular aspect of the present invention is the fabrication of an amorphous metal nitride with multi-layered structure before depositing the dielectric layer so that the dielectric layer is prevented from gradual crystallization. Hence, leakage current is minimized significantly. Aside from facilitating the formation of a dielectric layer with a higher dielectric constant and reducing the capacitor leakage current, the metal nitride with multi-layered structure also increases the crystallization temperature of the capacitor in a subsequent high temperature process. Moreover, the interfacial properties between the bottom electrode and the dielectric layer are also improved so that the stability and reliability of the device are significantly enhanced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A metal-insulator-metal (MIM) capacitor structure comprising a top electrode, a bottom electrode and a dielectric layer, wherein the dielectric layer is disposed between the top electrode and the bottom electrode, the MIM capacitor structure is characterized in that the bottom electrode comprises:
a conductive layer; and
a metal nitride with multi-layered structure disposed between the conductive layer and the dielectric layer, wherein the nitrogen content in the metal nitride with multi-layered structure gradually increases in the direction toward the dielectric layer, and the metal nitride with multi-layered structure is amorphous.

2. The MIM capacitor structure of claim 1, wherein a material of the conductive layer is substantially the same as that of the metal nitride with multi-layered structure.

3. The MIM capacitor structure of claim 1, wherein the material constituting the metal nitride with multi-layered structure includes titanium nitride (TiN) or tantalum nitride (TaN).

4. The MIM capacitor structure of claim 1, wherein the metal nitride with multi-layered structure comprises a plurality of ultra-thin films.

5. The MIM capacitor structure of claim 4, wherein each ultra-thin film in the metal nitride with multi-layered structure has a thickness between several angstroms to several tens of angstroms.

6. The MIM capacitor structure of claim 4, wherein the number of the ultra-thin films in the metal nitride with multi-layered structure is more than three.

7. The MIM capacitor structure of claim 1, wherein the material constituting the conductive layer includes titanium nitride (TiN), tantalum nitride (TaN), ruthenium (Ru), platinum (Pt) or polysilicon.

8. The MIM capacitor structure of claim 1, wherein a material of the dielectric layer comprises a high dielectric constant (high-k) material.

9. The MIM capacitor structure of claim 8, wherein the material constituting the dielectric layer includes tantalum oxide (Ta₂O₅), aluminum oxide (Al₂O₃), hafnium aluminum oxide (HfₓAl_{y}O), hafnium oxide (HfO₂) or titanium oxide (TiO₂).

10. A method of fabricating a metal-insulator-metal (MIM) capacitor, comprising the steps of:
providing a conductive layer;
forming a metal nitride with multi-layered structure over the conductive layer so that the two layers together form a bottom electrode, wherein the metal nitride with multi-layered structure is amorphous and the nitrogen content within the metal nitride with multi-layered structure gradually increases with the number of layers in the bottom electrode;
forming a dielectric layer over the metal nitride with multi-layered structure of the bottom electrode; and
forming a top electrode over the dielectric layer.

11. The method of fabricating the MIM capacitor of claim 10, wherein the step of forming the metal nitride with multi-layered structure over the conductive layer includes performing a deposition process using a vacuum film deposition system.

12. The method of fabricating the MIM capacitor of claim 11, wherein the vacuum film deposition system includes a chemical vapor deposition (CVD) system, a physical vapor deposition (PVD) system or an atomic layer deposition (ALD) system.

13. The method of fabricating the MIM capacitor of claim 10, wherein a material of the conductive layer is substantially the same as that of the metal nitride with multi-layered structure.

14. The method of fabricating the MIM capacitor of claim 10, wherein the material constituting the metal nitride with multi-layered structure includes titanium nitride (TiN) or tantalum nitride (TaN).

15. The method of fabricating the MIM capacitor of claim 10, wherein the metal nitride with multi-layered structure comprises a plurality of ultra-thin films.

16. The method of fabricating the MIM capacitor of claim 10, wherein the material constituting the conductive layer includes titanium nitride (TiN), tantalum nitride (TaN), ruthenium (Ru), platinum (Pt) or polysilicon.

17. The method of fabricating the MIM capacitor of claim 10, wherein a material of the dielectric layer comprises a high dielectric constant (high k) material.

18. The method of fabricating the MIM capacitor of claim 17, wherein the material constituting the dielectric layer includes tantalum oxide (Ta₂O₅), aluminum oxide (Al₂O₃), hafnium aluminum oxide (HfₓAl_{y}O), hafnium oxide (HfO₂) or titanium oxide (TiO₂).
